(19) United States
(12) Patent Application Publication
(10) Pub. No.: US 2019/0278166 A1
(43) Pub. Date: Sep. 12, 2019

(54) PHOTOLITHOGRAPHY SYSTEM AND METHOD USING A RETICLE WITH MULTIPLE DIFFERENT SETS OF REDUNDANT FRAMED MASK PATTERNS

(71) Applicant: GLOBALFOUNDRIES INC., GRAND CAYMAN (KY)

(72) Inventors: Lei Sun, Altamont, NY (US); Guoxiang Ning, Clifton Park, NY (US); Lloyd C. Litt, Latham, NY (US)

(73) Assignee: GLOBALFOUNDRIES INC., GRAND CAYMAN (KY)

(21) Appl. No.: 15/915,280

(22) Filed: Mar. 8, 2018

(51) Int. Cl. G03F 1/58; H01L 21/027; G03F 1/64; G03F 7/20; G03F 1/22

(52) U.S. Cl. CPC G03F 1/58; H01L 21/0274; G03F 1/64; G03F 7/70466; G03F 1/22; G03F 7/2004; G03F 7/70725; G03F 7/2022

(57) ABSTRACT

Disclosed is a reticle with multiple different sets of redundant mask patterns. Each set allows for patterning of a layer at a specific level of an integrated circuit (IC) chip design on a target region of a wafer using a vote-taking technique to avoid defects. The different sets further allow the same reticle to be used to pattern layers at different levels in the same IC chip design or to pattern layers at the same level or at different levels in different IC chip designs. Each mask pattern is individually framed with alignment marks to facilitate alignment minimize overlay errors. Optionally, redundant mask patterns in the same set are distributed across the reticle (as opposed to being located within the same general area) in order to minimize reticle overheating during patterning using the vote-taking technique. Also disclosed are a photolithography system and a photolithography method that employ such a reticle.

### BACKGROUND

### Field of the Invention

The present invention relates to photolithography and, particularly, to a reticle structure for use in photolithography (e.g., extreme ultraviolet (EUV) photolithography).

### Description of Related Art

Photolithography techniques are used to pattern features on semiconductor wafers during integrated circuit (IC) chip manufacturing. Advances in photolithography have, in part, enabled device scaling. Currently, extreme ultraviolet (EUV) photolithography is poised to complement and eventually replace conventional deep ultraviolet (DUV) photolithography due to the significantly narrower illumination wavelength (λ) used, which has the potential to potential to provide enhanced patterning resolution and lower process complexity, among other benefits. For example, EUV photolithography techniques employing EUV radiation with a wavelength (λ) of 13.5 nm may be used to achieve a less than 10 nm half pitch resolution at a single exposure, whereas DUV photolithography techniques employ DUV radiation with a wavelength (λ) of 193 nm in order to achieve a minimum 40 nm half pitch resolution at single exposure.

Although EUV photolithography techniques allow for device scaling, currently used reticle designs generally only contain the photomask pattern for a single layer of a single integrated circuit (IC) chip. One photomask pattern per reticle can, however, be very costly.

### SUMMARY

In view of the foregoing, disclosed herein are embodiments of a reticle structure that incorporates multiple different sets of redundant mask patterns. Each set of redundant mask patterns allows for patterning of a layer at a specific level of an integrated circuit (IC) chip design on a target region of a wafer using a vote-taking technique to avoid defects. Furthermore, the different sets of redundant mask patterns allow the same reticle to be used to pattern layers at different levels in the same IC chip design or to pattern layers at the same level or at different levels in different IC chip designs. The different IC chip designs can be at the same technology node or at different technology nodes. In any case, each mask pattern can be individually framed with alignment marks to facilitate alignment and minimize overlay errors. Optionally, redundant mask patterns in the same set can be distributed across the reticle (as opposed to being located within the same general area) in order to minimize reticle overheating during patterning using the vote-taking technique. Also disclosed herein are embodiments of a photolithography system and a photolithography method that employ such a reticle.

More particularly, disclosed herein are embodiments of a reticle for use in photolithography (e.g., for use in extreme ultraviolet (EUV) photolithography). The reticle can include a substrate. The reticle can further include pattern regions on the substrate. These pattern regions can include multiple instances of different patterns. For example, the pattern regions can include at least multiple instances of a first pattern and multiple instances of a second pattern that is different from the first pattern. The first pattern and the second pattern can, for example, be for layers at different levels within the same integrated circuit (IC) chip design. Alternatively, the first pattern and the second pattern can be for layers at the same level or at different levels within different IC chip designs. The reticle can also include frame regions on the substrate and bordering the pattern regions, respectively, such that each pattern region is framed. The reticle can further include separation regions on the substrate between adjacent frame regions such that the framed pattern regions are physically separated. Optionally, multiple instances of the same framed, pattern region can be distributed across the reticle (as opposed to being located within the same area).

Also disclosed herein are embodiments of a photolithography system that employs such a reticle. The system can include a light source, a reticle stage, and a wafer stage. The reticle stage can support the above-described reticle and the wafer stage can support a wafer. The light source, reticle and wafer can be positioned such that a surface of the wafer is adjacent to the pattern regions of the reticle and, particularly, such that light from the light source can be reflected off a pattern region of the reticle toward the surface of the wafer. The system can further include a controller, which is in communication with the light source, the reticle stage and the wafer stage. The controller can control the various other components of the system (e.g., based on user input received through a user interface) and, specifically, can cause a first set of exposure processes to be performed using the multiple instances of the first pattern on the reticle and can further cause a second set of exposure processes to be performed using the multiple instances of the second pattern on the reticle. During the first set of exposure processes, radiation from the light source can be reflected off of each of the multiple instances of the first pattern, in sequence, toward a first target region on the wafer in order to transfer a first image of the first pattern into the first target region. During the second set of exposure processes, radiation from the light source can be reflected off of each of the multiple instances of the second pattern, in sequence, toward a second target region on the wafer in order to transfer a second image of the second pattern into the second target region.

Also disclosed herein are embodiments of a photolithography method that employs such a reticle. The method can include providing the above-described reticle and system and positioning the light source, the reticle and the wafer such that a surface of the wafer is adjacent to the pattern regions of the reticle and, particularly, such that light from the light source can be reflected off a pattern region of the reticle toward the surface of the wafer. The method can include performing a first set of exposure processes using the multiple instances of the first pattern on the reticle. During the first set of exposure processes, radiation from the light source can be reflected off of each of the multiple instances of the first pattern, in sequence, toward a first target region on the wafer in order to transfer a first image of the first pattern into the first target region. The method can further include performing a second set of exposure processes using the multiple instances of the second pattern on the reticle. During the second set of exposure processes, radiation from the light source can be reflected off of each of the multiple instances of the second pattern, in sequence, toward a second target region on the wafer in order to transfer a second image of the second pattern into the second target region.

### BRIEF DESCRIPTION OF THE SEVERAL VIEWS OF THE DRAWINGS

The present invention will be better understood from the following detailed description with reference to the drawings, which are not necessarily drawn to scale and in which:

FIG. 1 is a schematic diagram illustrating an embodiment of a photolithography system that employs a reticle with multiple different sets of redundant patterns, each of which are individually framed;

FIGS. 2A-2G are diagrams illustrating exemplary layouts, respectively, for multiple different sets of redundant patterns on a reticle;

FIGS. 3A-3C are cross-section drawings, each illustrating a portion of a reticle that includes two adjacent framed pattern regions; and

FIG. 4 is a flow diagram illustrating an embodiment of a photolithography method that employs a reticle with multiple different sets of redundant patterns, each of which are individually framed.

### DETAILED DESCRIPTION

As mentioned above, photolithography techniques are used to pattern features on semiconductor wafers during integrated circuit (IC) chip manufacturing. Advances in photolithography have, in part, enabled device scaling. Currently, extreme ultraviolet (EUV) photolithography is poised to complement and eventually replace conventional deep ultraviolet (DUV) photolithography due to the significantly narrower illumination wavelength (λ) used, which has the potential to potential to provide enhanced patterning resolution and lower process complexity, among other benefits. For example, EUV photolithography techniques employing EUV radiation with a wavelength (λ) of 13.5 nm may be used to achieve a less than 10 nm half pitch resolution at a single exposure, whereas DUV photolithography techniques employ DUV radiation with a wavelength (λ) of 193 nm in order to achieve a minimum 40 nm half pitch resolution at single exposure. Although EUV photolithography techniques allow for device scaling, currently used reticle designs generally only contain the photomask pattern for a single layer of a single integrated circuit (IC) chip. One photomask pattern per reticle can, however, be very costly.

In view of the foregoing, disclosed herein are embodiments of a reticle structure that incorporates multiple different sets of redundant mask patterns. Each set of redundant mask patterns allows for patterning of a layer at a specific level of an integrated circuit (IC) chip design on a target region of a wafer using a vote-taking technique to avoid defects. Furthermore, the different sets of redundant mask patterns allow the same reticle to be used to pattern layers at different levels in the same IC chip design or to pattern layers at the same level or at different levels in different IC chip designs. The different IC chip designs can be at the same technology node or at different technology nodes. In any case, each mask pattern can be individually framed with alignment marks to facilitate alignment minimize overlay errors. Optionally, redundant mask patterns in the same set can be distributed across the reticle (as opposed to being located within the same general area) in order to minimize reticle overheating during patterning using the vote-taking technique. Also disclosed herein are embodiments of a photolithography system and a photolithography method that employ such a reticle.

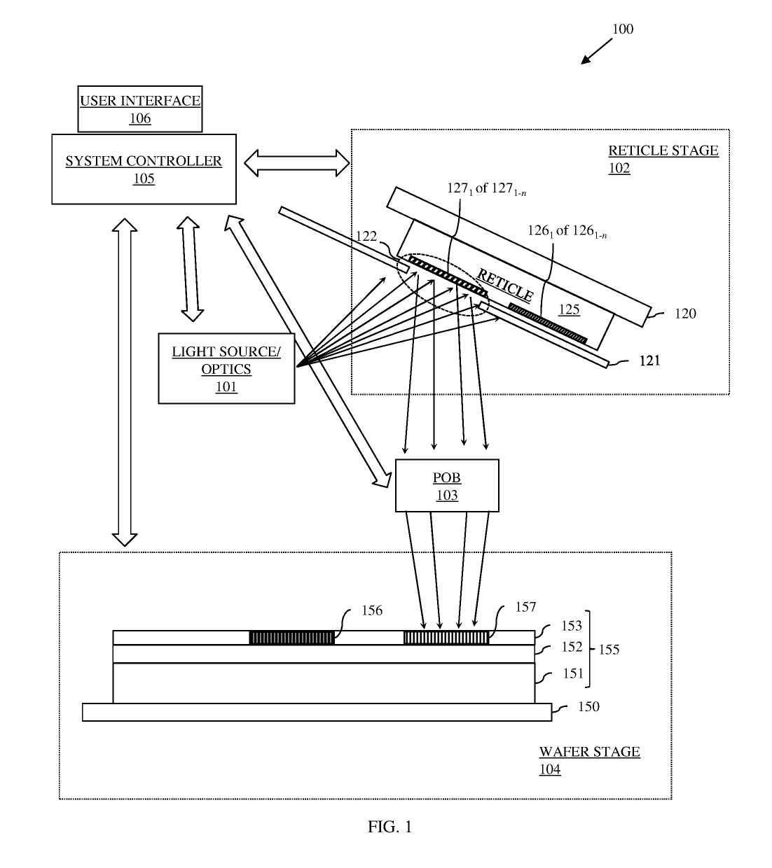

More particularly, referring to FIG. 1, disclosed herein are embodiments of a unique reticle 125 and of a photolithography system 100 (e.g., an extreme ultraviolet (EUV) photolithography system) that employs the reticle 125.

As with conventional EUV reticles, the reticle 125 can include substrate, a reflective multilayer stack on the substrate, a protective layer on the multilayer stack and a light absorber layer on the protective layer. However, rather than including a single framed pattern region on the substrate and, particularly, in the light absorber layer, the disclosed reticle 125 includes multiple framed pattern regions on the substrate and separated by separation regions.

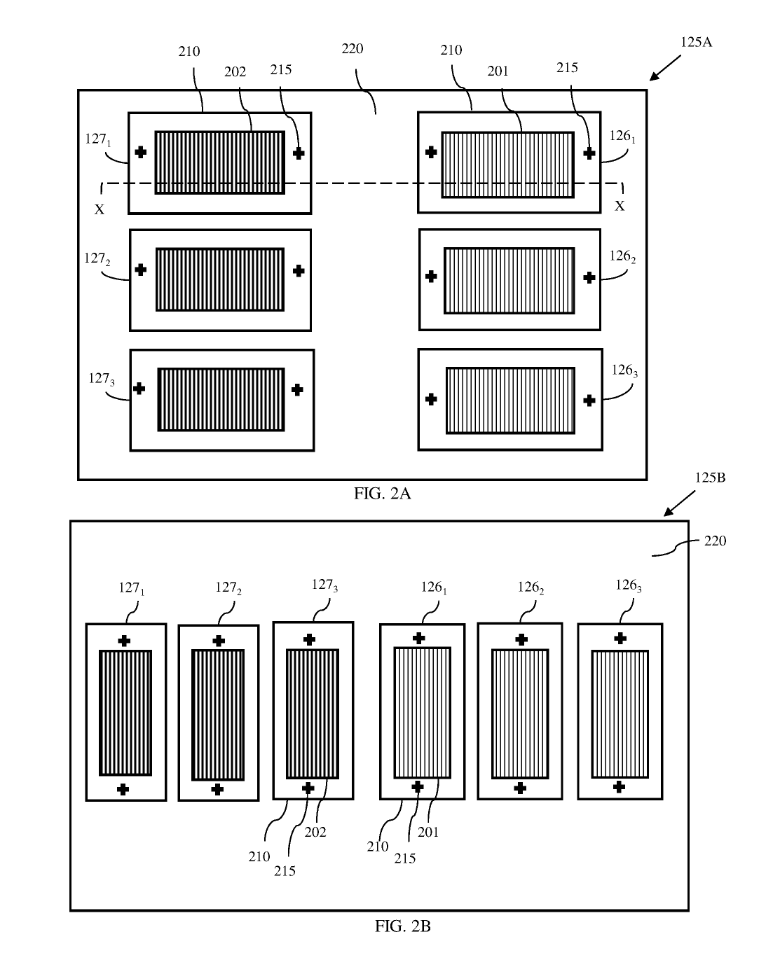

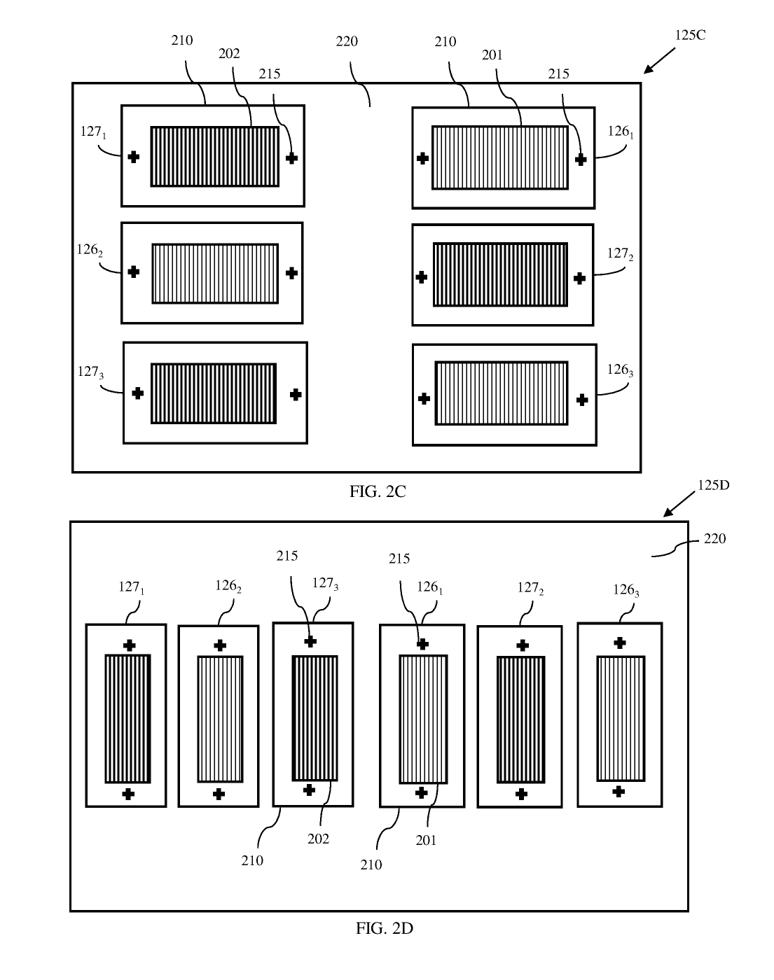

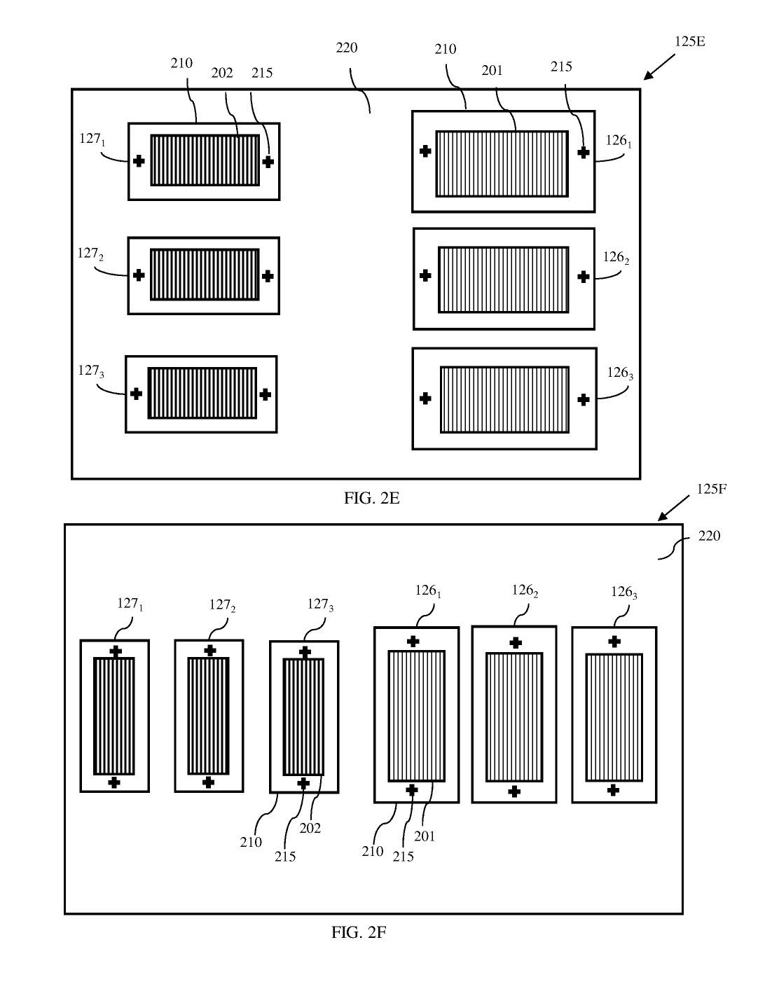

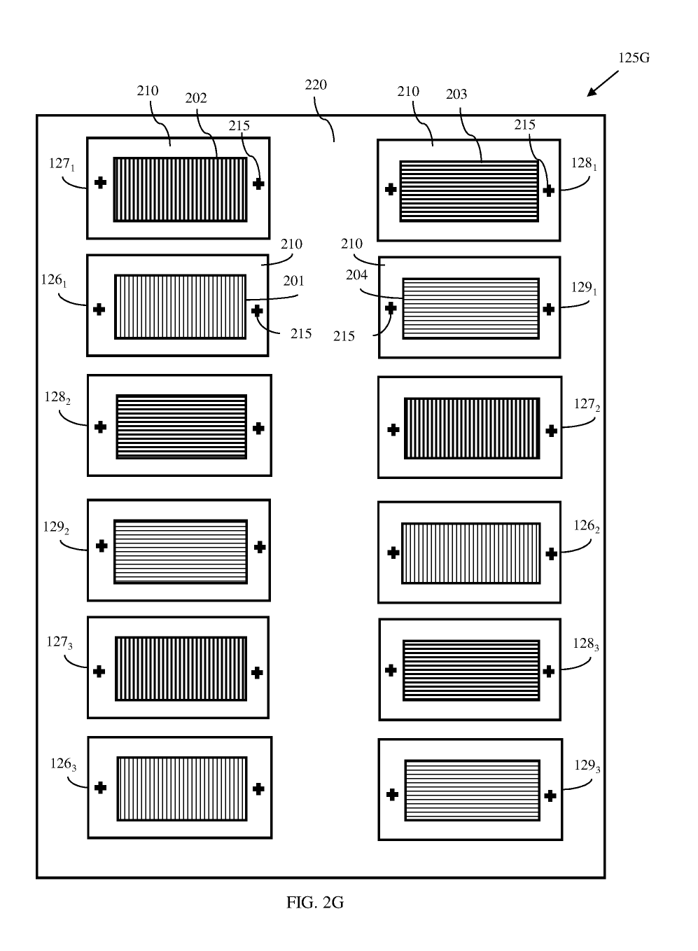

As illustrated in the various exemplary reticle embodiments 125A-125G shown in FIGS. 2A-2G, respectively, the framed pattern regions on the substrate of the reticle 125 can be multiple instances of different patterns in the light absorber layer (e.g., see patterns 201 and 202 and, optionally, patterns 203, 204, etc.). Each pattern can be bordered by a frame region 210. Additionally, each frame region 210 can have one or more alignment marks 215 thereon and adjacent frame regions can be physically separated by separation regions 220.

Specifically, as illustrated in FIGS. 2A-2F, the framed pattern regions can include at least framed first pattern regions 126₁₋ₙ and framed second pattern regions 127₁₋ₙ. The framed first pattern regions 126₁₋ₙ can include multiple instances of the same first pattern 201 in the light absorber layer, where each instance is bordered by a corresponding frame region 210 having one or more alignment marks 215. The framed second pattern regions 127₁₋ₙ can include multiple instances of a second pattern in the light absorber layer and different from the first pattern, where each instance is similarly bordered by a corresponding frame region 210 having one or more alignment marks 215. Optionally, as illustrated in FIG. 2G, the framed pattern regions can further include: framed third pattern regions 128₁₋ₙ (i.e., multiple instances of a third pattern 203 bordered by frame regions 210 with alignment marks 215), framed fourth pattern regions 129₁₋ₙ (i.e., multiple instances of a fourth pattern 204 bordered by frame regions 210 with alignment marks 215), and so on.

Those skilled in the art will recognize that, during EUV photolithography, EUV light is used to transfer an image of a pattern on a reticle into a photosensitive layer 153, which is above a feature layer 152 on a substrate 151 of semiconductor wafer 155. Portions of the photosensitive layer exposed to light undergo a chemical change. This chemical change will make the exposed areas either soluble in a photoresist developer (e.g., in the case of a positive tone photoresist) or insoluble in a photoresist developer (e.g., in the case of a negative tone photoresist). After an exposure process, the photosensitive layer can be developed to remove soluble portions and an etch process can be performed to then transfer the pattern into the feature layer below.

With the reticle 125, the different patterns (i.e., the first pattern 201, the second pattern 202, the third pattern 203 (if present), the fourth pattern 204 (if present), etc.) of the framed pattern regions can represent shapes to be patterned into feature layers at different levels of the same integrated circuit (IC) chip design. That is, the first pattern 201 can be for patterning shapes in a first feature layer at one level of an IC chip design, the second pattern 202 can be for patterning shapes in a second feature layer at a higher level of the same IC chip design, the third pattern 203 (if present) can be for patterning shapes in a third feature layer at an even high layer of the same IC chip design, and so on. Those skilled in the art will recognize that these levels can include, but are not limited to: an active device level, a gate polysilicon level; middle of the line contact levels; different back end of the line (BEOL) metal levels; etc.

Alternatively, the different patterns (i.e., the first pattern 201, the second pattern 202, the third pattern 203 (if present), the fourth pattern 204 (if present), etc.) in the light absorber layer can represent shapes to be patterned into feature layers at the same level or at different levels within different IC chip designs that are to be manufactured on the same wafer or on different wafers. The first pattern 201 can be for patterning shapes in a feature layer at one level of an IC chip with one design. The second pattern 202 can be for patterning shapes in a feature layer at the same level or a different level of an IC chip with a different design. The third pattern 203 (if present) can be for patterning shapes in a feature layer at the same level or a different level of an IC chip with yet another design, and so on.

It should be noted that the different IC chip designs can be at the same technology node. Alternatively, the different IC chip designs can be at different technology nodes (e.g., 5LP and 7LP technology nodes, respectively, or any other two different technology nodes that use the same mask process). Additionally, it should also be noted that, when the patterns are for feature layers at the same level or at different levels of different IC designs, the reticle 125 can be customized for a single customer that manufactures IC chips according to all of the different IC designs. Alternatively, the reticle 125 can be customized for multiple customers, each of whom manufacture IC chips according to at least one of the IC designs, when such customers agree to reticle sharing (e.g., to minimize costs). Finally, it should be noted that, when the patterns are for feature layers at the same level or at different levels of different IC chip designs provided, for example, by different customers, the sizes of the patterns to correspond to varying chip sizes (e.g., as illustrated in the embodiments 125E and 125F of FIGS. 2E and 2F, respectively).

In any case, the framed pattern regions can be arranged on the reticle in rows and/or columns. For example, as illustrated in the exemplary embodiments 125A of FIG. 2A, 125C of FIG. 2C, 125E of FIG. 2E, and 125G of FIG. 2G, the framed pattern regions can be arranged in multiple rows and columns; whereas, as illustrated in the exemplary embodiments 125B of FIG. 2B, 125D of FIG. 2D and 125F of FIG. 2F, the framed pattern regions can be arranged in a single row or column. It should be understood that the exemplary configurations shown in FIGS. 2A-2G are not intended to be limiting and that any number of rows and/or columns of framed pattern regions (including multiple instances of at least two different patterns) are anticipated (e.g., 1×4, 1×6, 1×8, . . . , 2×2, 2×3, 2×4, etc.).

The framed pattern regions can further be arranged on the reticle such that multiple instances of the same pattern (i.e., multiple instances of the first pattern 201, multiple instances of the second pattern 202, etc.) are located within the same general area. For example, as illustrated in the exemplary embodiments 125A of FIG. 2A and 125E of FIG. 2E, the framed first pattern regions 126₁₋ₙ can all be in one column above a first area of the substrate and the framed second pattern regions 127₁₋ₙ can all be in a different column above a second area of the substrate. In another embodiment, the framed first pattern regions 126₁₋ₙ can all be in one row above a first area of the substrate and the framed second pattern regions 127₁₋ₙ can all be in a different row above a second area of the substrate (not shown). Similarly, as illustrated in the embodiments 125B of FIG. 2B and 125F of FIG. 2F, the framed first pattern regions 126₁₋ₙ can all be at one end of a row above a first area of the substrate and the framed second pattern regions 127₁₋ₙ can all be at the opposite end of the same row above a second area of the substrate. In yet another embodiment, the framed first pattern regions 126₁₋ₙ can all be at one end of a column above a first area of the substrate and the framed second pattern regions 127₁₋ₙ can all be at the opposite end of the same column above a second area of the substrate (not shown).

Alternatively, multiple instances of the same pattern (i.e., multiple instances of the first pattern 201, multiple instances of the second pattern 202, etc.) can be distributed across the substrate. Distribution can, for example, be approximately uniform such that adjacent patterns are different. For example, as illustrated in the exemplary embodiment 125C of FIG. 2C, the framed first pattern regions 126₁₋ₙ and the framed second pattern regions 127₁₋ₙ can be distributed throughout the rows and columns so as to avoid placing any two of the same pattern in adjacent positions. Similarly, as illustrated in the exemplary embodiment 125D of FIG. 2D, the framed first pattern regions 126₁₋ₙ and the framed second pattern regions 127₁₋ₙ can be distributed throughout a single row (as shown) or a single column so as to avoid placing any two of the same pattern in adjacent positions. Similarly, as illustrated in the exemplary embodiment 125G of FIG. 2G, the framed first pattern regions 126₁₋ₙ, the framed second pattern regions 127₁₋ₙ, the framed third pattern regions 128₁₋ₙ, and the framed fourth pattern regions 129₁₋ₙ can be distributed throughout the rows and columns so as to avoid placing any two of the same pattern in adjacent positions. Although not show in the Figures, different sized patterns can similarly be distributed approximately uniformly across the substrate (as opposed to contained within specific areas, as shown in FIGS. 2E and 2F). As discussed in greater detail below, with regard to operation of the system 100, distribution of the multiple instances of the same pattern across the reticle can minimize reticle overheating when vote-taking patterning techniques are performed using the reticle.

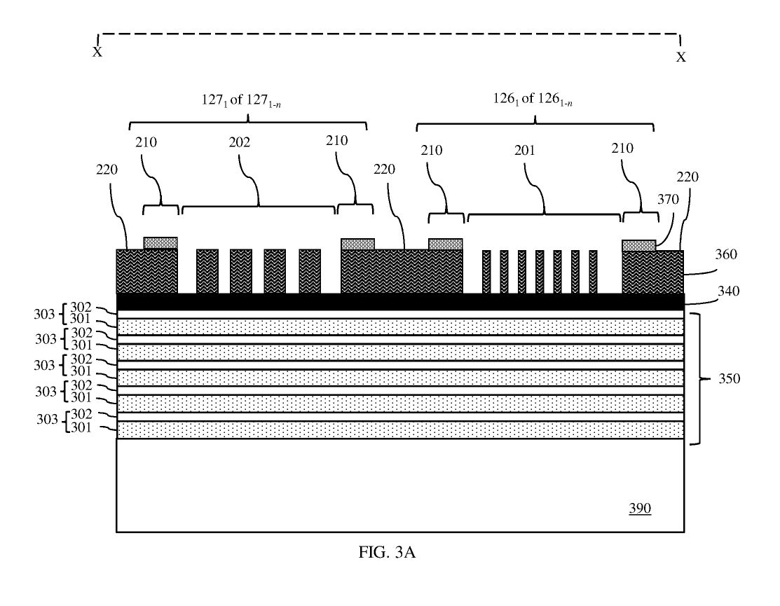

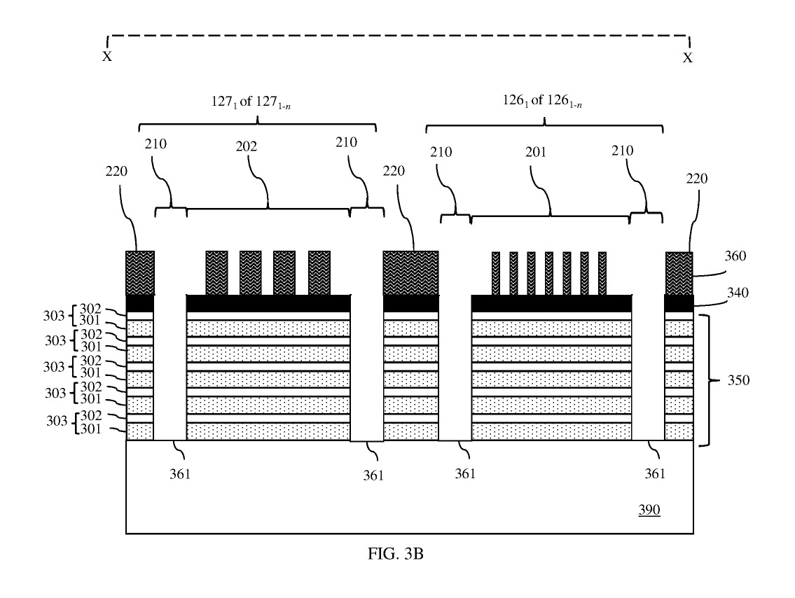

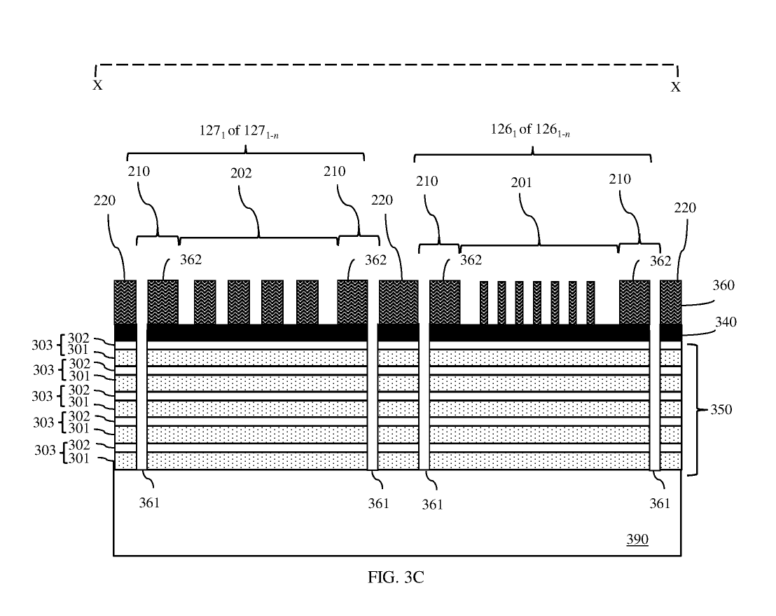

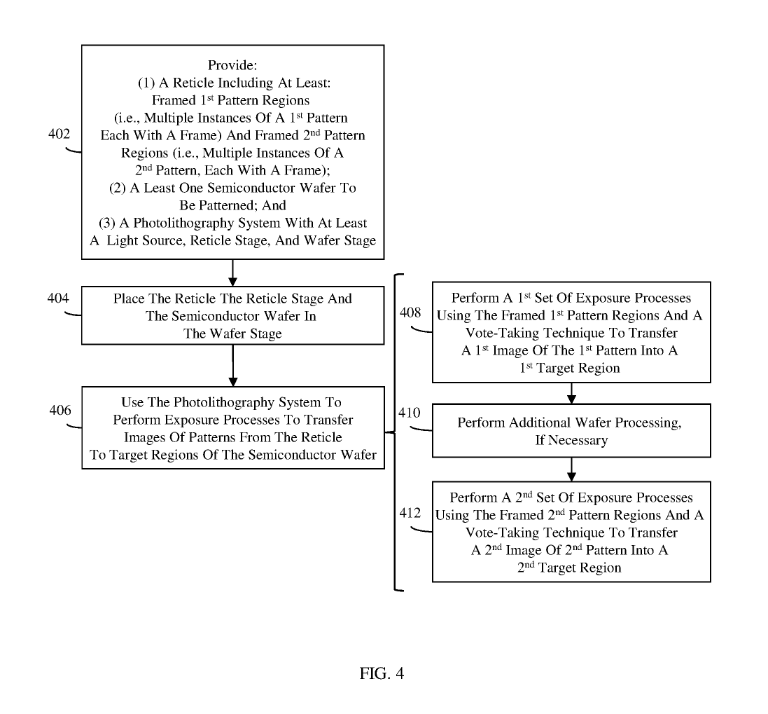

FIGS. 3A-3C are cross-section drawings, each illustrating a portion of a reticle 125 that includes two adjacent framed pattern regions with different patterns and further illustrating in greater detail the above-mentioned components of the reticle 125. Specifically, as mentioned above, each reticle 125 can include a substrate 390, a reflective multilayer stack 350 on the substrate 390, a protective layer 340 on the reflective multilayer stack 350 and a light absorber layer 360 on the protective layer 340.

The substrate 390 can, for example, be made of a low thermal expansion material (LTEM). That is, the substrate 390 can be a LTEM substrate. Those skilled in the art will recognize that thermal expansion refers to the tendency to change shape, area and volume in response to changes in temperature. Exemplary low thermal expansion materials that can be used for the substrate 390 include fused silica, fused quartz, calcium fluoride (CaF₂), silicon carbide, black diamond, silicon oxide-titanium oxide (SiO₂—TiO₂) alloy and/or any other suitable LTEM known in the art.

The reflective multilayer stack 350 can include alternating layers of high and low atomic number materials. That is, the reflective multilayer stack 350 can have multiple pairs 303 of layers, wherein each pair 303 includes a first layer 301 and a second layer 302 on the first layer 301 and wherein the first layer 301 has a higher atomic number than the second layer 302 (i.e., the first layer 301 has a relatively high atomic number and the second layer 302 has a relatively low atomic number). For example, the first layers 301 can be molybdenum with an atomic number of 42 and the second layers 302 can be silicon with an atomic number of 14 or beryllium with an atomic number of 4. In any case, the first layers and the second layers can be highly reflective of light at the wavelengths being used in the photolithography process at issue (e.g., highly reflective at the extreme ultraviolet (EUV) wavelength range of 11-14 nm and, particularly at the EUV wavelength of 13.5 nm) and the layers in each pair 303 of layers can have a combined thickness that is approximately equal to the EUV wavelength being used in the photolithography process at issue. For example, if the EUV wavelength is 13.5 nm, then the combined thickness of the layers in each pair of layers can be 6.5-7 nm. Thus, each pair 303 of layers effectively forms a EUV mirror.

The protective layer 340 can be on and immediately adjacent to the uppermost layer in the reflective multilayer stack 350. The material of the protective layer 340 can be different from that of the first layers 301, the second layers 302 and the light absorbing material(s) of the light absorber layer 360 (as discussed below). Specifically, the material of the protective layer 340 can have different etch characteristics than the materials of the first layers 301, the second layer 302, and the light absorbing material(s) of the light absorber layer 360 and can be highly reflective at the wavelengths being used in the photolithography process at issue (e.g., highly reflective at the extreme ultraviolet (EUV) wavelength range of 11-14 nm). For example, the material of the protective layer 340 can be ruthenium with an atomic number of 44 or an alloy of ruthenium, such as, ruthenium boride or ruthenium silicide. The protective layer 340 can have a thickness of, for example, 1-4 nm.

The light absorber layer 360 can be made of light absorbing material(s) that absorb light and, particularly, that absorb light at the wavelengths being used in the photolithography process at issue (e.g., that absorbs light at the extreme ultraviolet (EUV) wavelength range of 11-14 nm and, particularly, at the EUV wavelength of 13.5 nm). Exemplary light absorbing materials can include, but are not limited to, chromium, nickel, titanium, tantalum, aluminum, palladium, or light absorbing alloys thereof. Thus, the light absorber layer 360 can include, for example, one or more layers of tantalum boron nitride, tantalum nitride and/or tantalum oxynitride.

The different patterns 201, 202, etc., of the different framed patterned regions 216₁₋ₙ, 217₁₋ₙ, etc., can be patterned portions of the light absorber layer 360. That is, they can be portions of the light absorber layer 360 that have been etched (e.g., using conventional lithographic patterning and etch techniques) so as to include a pattern of shapes in an area above the protective layer 340. As illustrated, within each pattern portions of the top surface of the protective layer 340 adjacent to the shapes are exposed.

FIGS. 3A-3C further show three different possible configurations for the frame regions 210 that border each of the patterns 201, 202, etc., in each of the framed patterned regions.

Specifically, as illustrated in FIG. 3A, the reticle 125 can further include an additional light absorber layer 370 above and immediately adjacent to light absorber layer 360. The additional light absorber layer 370 can be made of a different light absorbing material than the light absorber layer 360. For example, if the light absorber layer 360 is made of tantalum boron nitride, the additional light absorber layer 370 can be made of tantalum nitride or tantalum oxynitride. In any case, the frame regions 210 can be patterned portions of this additional light absorber layer 370. That is, the frame regions 210 can be portions of the additional light absorber layer 370 that have been etched (e.g., using conventional lithographic patterning and etch techniques) into frame shapes on the top surface of the light absorber layer 360. Each frame shape has a center opening that exposes one of the patterns in the light absorber layer 360 below such that the frame region 210 borders that pattern. The separation regions 220 can include the non-patterned portions of the light absorber layer 360 that extend laterally beyond the outer edges of the frame shapes and, particularly, that extend between adjacent frame regions 210.

Alternatively, as illustrated in FIG. 3B, the reticle 125 can further include trenches 361 (also referred to herein as black border) that extend vertically through the light absorber layer 360, through the protective layer 340 and through the reflective multilayer stack 350 to the top surface of the substrate 390. The trenches 361 can be lithographically patterned and then etched so that each trench borders (i.e., surrounds) one of the patterns in the light absorbing layer and, thereby forms a frame region 210 around that pattern. The separation regions 220 can include the non-patterned portions of the light absorber layer 360 that extend laterally beyond the outer edges of the trenches 361 and, particularly, that extend between adjacent frame regions 210.

Alternatively, as illustrated in FIG. 3C, the frame regions 210 can include a combination of additional patterned portions of the light absorber layer 360 and trenches 361. Specifically, as mentioned above, the different patterns 201, 202, etc., of the different framed patterned regions 216₁₋ₙ, 217₁₋ₙ, etc., can be patterned portions of the light absorber layer 360. The light absorber layer 360 can further have additional patterned portions 362 that have been etched (e.g., using conventional lithographic patterning and etch techniques) into frame shapes on the top surface of the protective layer 340. Each frame shape has a center portion that contains one of the patterns (i.e., each frame shape borders one of the patterns). The reticle 125 can further include trenches 361 (also referred to herein as black border) that extend vertically through the light absorber layer 360, through the protective layer 340 and through the reflective multilayer stack 350 to the top surface of the substrate 390. Each trench 361 can be formed (e.g., lithographically patterned and etched) so as to border the outer edge of one of the frame shapes and, thereby one of the patterns. Thus, the combination of a frame shape 362 and its adjacent trench 361 forms a frame region 210 around each pattern. The separation regions 220 can include the non-patterned portions of the light absorber layer 360 that extend laterally beyond the outer edges the trenches 361 and, particularly, that extend between adjacent frame regions 210.

As mentioned above and illustrated in FIGS. 2A-2G, each frame region 210 can further have alignment mark(s) 215 (not shown in FIGS. 3A-3C) to facilitate alignment and improve overlay results during subsequent wafer patterning.

Referring again to FIG. 1, in addition to the reticle 125, the photolithography system 100 can further include, but is not limited to, the following components: a light source 101, a reticle stage 102, a projections optics box (POB) 103, and a wafer stage 104. The photolithography system 100 can also further include a controller 105 in communication with and adapted to control the light source 101, reticle stage 102, POB 103 and wafer stage 104. The photolithography system 100 can also further include a user interface 106 adapted to allow a user to communicate with the controller 105 and set parameters for performing photolithography operations.

The reticle stage 102 can include the reticle 125, as described in detail above. The bottom surface of the reticle 125 can be detachably coupled (e.g., by means of a reticle chuck (not shown)) to a movable support surface 120. This movable support surface 120 can support the reticle 125 and can further move the reticle 125 (e.g., by means of a reticle positioning system (not shown)). The reticle stage 102 can further include movable reticle masking (REMA) blades 121. The REMA blades 121 can be mounted on the support surface 120 and can be positioned adjacent to the framed pattern regions of the reticle 125 opposite the support surface 120. Movement of the movable REMA blades 121 can be selectively controllable (e.g., by the controller 105) so that an opening 122 is created due to the relative positioning of the blades and this opening 122 can, for example, expose only a selected one of the framed patterned regions (e.g., framed patterned region 127₁, as illustrated) on the reticle 125 at a time.

The light source 101 (and corresponding optics) can be capable of generating radiation and directing that radiation toward the opening 122 in the REMA blades 121 of the reticle stage 102. For example, the light source 101 can be an extreme ultraviolet (EUV) light source capable of generating EUV light with a wavelength (λ) in the range of 11-14 nm (e.g., with a λ=13.5 nm) and aiming beams of that EUV light toward the reticle stage 102.

The projections optics box (POB) 103 (also referred to as a projections optics assembly) can receive (i.e., capture or collect) reflected light from the reticle stage 102. The POB 103 can, for example, filter the captured light (e.g., to remove non-diffracted light) and can directed the filtered light toward the wafer stage 104. Such EUV photolithography systems are well known in the art and, thus, the specific details of the components described above including the light source 101 and POB 103 are omitted from this specification in order to allow the reader to focus on the salient aspects of the disclosed invention.

The wafer stage 104 can include a movable support surface 150. A semiconductor wafer 155 can be detachably coupled (e.g., by means of a wafer chuck (not shown)) to the movable support surface 150. This movable support surface 120 can support the semiconductor wafer 155 and can further move the semiconductor wafer 155 (e.g., by means of a wafer positioning system (not shown)). As discussed above, the semiconductor wafer 155 can include a substrate 151, a feature layer 152 to be patterned on the substrate 151 and a photosensitive layer 153 on the feature layer 152. It should be understood that the feature layer to be patterned can be an upper portion of a bulk semiconductor substrate or, alternatively, a discrete feature layer to be patterned and the substrate can, optionally, include already patterned feature layers.

It should be understood that the controller 105 can control exposure processes that are performed by the photolithography system 100 (e.g., as directed by user inputs) and, during these exposure processes, can position the light source 101 (and corresponding optics), the reticle 125, the REMA blades 121, the POB 103 and the semiconductor wafer 155 relative to each other so that light from the light source 101 can be directed toward the opening 122 in the REMA blades 121 in order to expose a single framed pattern region within the opening 122, so that light reflected off of that exposed framed pattern region can be captured and filtered by POB 103, and so that light filtered by the POB 103 can further be directed toward the portion of the photosensitive layer 153 in the target region of the semiconductor wafer 155.

Furthermore, given the unique structure of the reticle 125 with multiple framed pattern regions, the controller 105 can cause various different sets of exposure processes to be performed.

For example, the controller 105 can cause a first set of exposure processes to be performed using the framed first pattern regions 126₁₋ₙ (i.e., the multiple instances of the first pattern 201) on the reticle 125. During the first set of exposure processes, the controller 105 can cause radiation (e.g., EUV light) from the light source 101 (and corresponding optics) to be reflected off of each of the multiple instances of the first pattern 201, in sequence, toward a portion of the photosensitive layer 153 in a first target region 156 on the semiconductor wafer in order to transfer a first image of the first pattern 201 into the first target region 156 and, particularly, into that portion of the photosensitive layer. This first set of exposure processes can be used to implement a vote-taking technique wherein each one of the framed first pattern regions 126₁₋ₙ is individually and, in sequence, exposed to an equal fraction of a nominal exposure dose of light from the light source 101. When exposure of each of the framed first pattern regions is completed, transfer of the first image of the first pattern 201 into the first target region 156 will also be completed. Since any random defect present on any of the framed first pattern regions will only be subjected to a fraction of the exposure dose, the impact of that random defect on the image transferred into the first target region 156 will be minimized.

The controller 105 can subsequently cause a second set of exposure processes to be performed using the framed second pattern regions 127₁₋ₙ (i.e., the multiple instances of the second pattern 202) on the reticle 125. Specifically, during the second set of exposure processes, the controller 105 can cause radiation (e.g., EUV light) from the light source 101 (and corresponding optics) to be reflected off of each of the multiple instances of the second pattern 202, in sequence, toward a portion of a photosensitive layer in a second target region 157 on the same semiconductor wafer (as illustrated) or on a different semiconductor wafer in order to transfer a second image of the second pattern 202 into that portion of that photosensitive layer. Again, the second set of exposure processes can be used to implement a vote-taking technique wherein each one of the framed second pattern regions 127₁₋ₙ is individually and, in sequence, exposed to an equal fraction of a nominal exposure dose of light from the light source 101. When exposure of each of the framed second pattern regions is completed, transfer of the second image of the second pattern 202 into the second target region 157 will also be completed. Since any random defect present on any of the framed second pattern regions will only be subjected to a fraction of the exposure dose, the impact of that random defect on the image transferred into the second target region 157 will be minimized.

If applicable (e.g., if the embodiment 125G of FIG. 2G is employed), the controller 105 can similarly cause a third set of exposure processes to be performed using framed third pattern regions 128₁₋ₙ to pattern a third target region and can further cause a fourth set of exposure process to be performed using framed fourth pattern regions 129₁₋ₙ to pattern a fourth target region.

As mentioned above and illustrated in FIGS. 2C, 2D and 2G, multiple instances of the same pattern (i.e., multiple instances of the first pattern 201, multiple instances of the second pattern 202, etc.) can be distributed across the substrate of the reticle 125. Distribution of the multiple instances of the same pattern across the substrate is particularly useful when using the above-described vote technique to pattern target regions. Specifically, if all of the instances of a pattern are located in the same general area of a reticle, the repeated exposure processes can overheat the reticle in that area and such overheating can alter the pattern shapes. By distributing the multiple instances of the same pattern across the substrate, the repeated exposure processes are performed across different areas and, thus, minimizes any overheating of a single area.

It should be understood that IC chips with different designs can be formed on the same semiconductor wafer using the photolithography system 100 described above. Thus, when the various different patterns (i.e., the first pattern 201, the second pattern 202, etc.) in the framed pattern regions on the reticle 125 are designed to pattern feature layers at the same level for different IC chip designs, then the different sets of exposure processes can be performed one after the other without additional processing of the semiconductor wafer. That is, if the first pattern 201 is for patterning a layer at a specific level (e.g., at the active device level or some other specific level) of an IC chip being formed in a first target region of the semiconductor wafer 155 according to a first IC chip design and if the second pattern 202 is for patterning a layer at the same specific level of another IC chip being formed in a second target region of the semiconductor wafer 155 according to a second IC chip design, then the first set of exposure processes can be followed by the second exposure processes to transfer images into different portions of the same photosensitive layer in different target regions, respectively. Any adjustments to the exposure parameters (e.g., dose, etc.) can be made, as necessary, between the sets of exposure processes. In this case, after both sets of exposure processes are performed, the images of the patterns in the different portions of the photosensitive layer can simultaneously be transferred into corresponding portions of the feature layer (e.g., an active device layer, a gate polysilicon layer, etc.) below the photosensitive layer and in the different target regions, respectively. This transfer can be achieved using, for example, conventional photosensitive layer development and feature layer etch processes.

However, when the first pattern and the second pattern are designed to pattern feature layers at different levels of either the same IC chip design or different IC chip designs, the semiconductor wafer must subjected to additional processing between the first set of exposure processes and the second set of exposure processes. This additional processing can include, but is not limited to, the following: transferring the first image of the first pattern from a portion of the photosensitive layer into a corresponding portion of a feature layer (e.g., an active device layer) below the photosensitive layer and in the first target region (e.g., by conventional photosensitive layer development and feature layer etch processes); depositing at least one additional feature layer to be patterned (e.g., deposition of a gate polysilicon layer on the active device layer); and depositing an additional photosensitive layer on the additional feature layer to be patterned. The second set of exposure processes can then be performed, after which, the second image of the second pattern can be transferred from a portion of the additional photosensitive layer into a corresponding portion of the additional feature layer below the additional photosensitive layer (e.g., by conventional photosensitive layer development and feature layer etch processes).

Referring to the flow diagram of FIG. 4, also disclosed herein are embodiments of a photolithography method implemented using the above-described reticle 125 and photolithography system 100. Specifically, a system 100, a reticle 125 and at least one semiconductor wafer 155, as described in detail above, can be provided (see process 402 and FIGS. 1-3C). The reticle 125 can be placed in the reticle stage 102 and the semiconductor wafer 155 can be placed in the wafer stage 104 (see process 404 and FIG. 1). Exposure processes can then be performed using the photolithography system 100 (e.g., as directed by user inputs) to transfer images of patterns (e.g., patterns 201 and 202) from the reticle 125 to target regions (e.g., target regions 156 and 157, respectively) on the semiconductor wafer 155 (see process 406 and FIG. 1). It should be noted that, during these exposure processes, the light source 101 (and corresponding optics), the reticle 125, the REMA blades 121, the POB 103 and the semiconductor wafer 155 can be positioned relative to each other so that light from the light source 101 is directed toward the opening 122 in the REMA blades 121 in order to expose a single framed pattern region within the opening 122, so that light reflected off of that exposed framed pattern region is captured and filtered by POB 103, and so that light filtered by the POB 103 is further directed toward a target region of the photosensitive layer 153 of the semiconductor wafer 155.

More specifically, given the unique structure of the reticle 125 with multiple framed pattern regions, the exposure processes can include different sets of exposure processes (see processes 408-412).

For example, a first set of exposure processes can be performed using the framed first pattern regions 126₁₋ₙ (i.e., the multiple instances of the first pattern 201) on the reticle 125 (see process 408). During the first set of exposure processes, radiation (e.g., EUV light) from the light source 101 (and corresponding optics) can be reflected off of each of the multiple instances of the first pattern 201, in sequence, toward a portion of the photosensitive layer 153 in a first target region 156 on the semiconductor wafer in order to transfer a first image of the first pattern 201 into the first target region 156 and, particularly, into that portion of the photosensitive layer. This first set of exposure processes can be used to implement a vote-taking technique wherein each one of the framed first pattern regions 126₁₋ₙ is individually and, in sequence, exposed to an equal fraction of a nominal exposure dose of light from the light source 101. When exposure of each of the framed first pattern regions is completed, transfer of the first image of the first pattern 201 into the first target region 156 will also be completed. Since any random defect present on any of the framed first pattern regions will only be subjected to a fraction of the exposure dose, the impact of that random defect on the image transferred into the first target region 156 will be minimized.

Subsequently, a second set of exposure processes to be performed using the framed second pattern regions 127₁₋ₙ (i.e., the multiple instances of the second pattern 202) on the reticle 125 (see process 412). During the second set of exposure processes, radiation (e.g., EUV light) from the light source 101 (and corresponding optics) can be reflected off of each of the multiple instances of the second pattern 202, in sequence, toward a portion of a photosensitive layer in a second target region 157 on the same semiconductor wafer (as illustrated) or on a different semiconductor wafer in order to transfer a second image of the second pattern 202 into that portion of that photosensitive layer. Again, the second set of exposure processes can be used to implement a vote-taking technique wherein each one of the framed second pattern regions 127₁₋ₙ is individually and, in sequence, exposed to an equal fraction of a nominal exposure dose of light from the light source 101. When exposure of each of the framed second pattern regions is completed, transfer of the second image of the second pattern 202 into the second target region 157 will also be completed. Since any random defect present on any of the framed second pattern regions will only be subjected to a fraction of the exposure dose, the impact of that random defect on the image transferred into the second target region 157 will be minimized.

If applicable (e.g., if the embodiment 125G of FIG. 2G is employed), a third set of exposure processes can be performed using framed third pattern regions 128₁₋ₙ to pattern a third target region and a fourth set of exposure process can be performed using framed fourth pattern regions 129₁₋ₙ to pattern a fourth target region.

As mentioned above and illustrated in FIGS. 2C, 2D and 2G, multiple instances of the same pattern (i.e., multiple instances of the first pattern 201, multiple instances of the second pattern 202, etc.) can be distributed across the substrate of the reticle 125. Distribution of the multiple instances of the same pattern across the substrate is particularly useful when using the above-described vote technique to pattern target regions. Specifically, if all of the instances of a pattern are located in the same general area of a reticle, the repeated exposure processes can overheat the reticle in that area and such overheating can alter the pattern shapes. By distributing the multiple instances of the same pattern across the substrate, the repeated exposure processes are performed across different areas and, thus, minimizes any overheating of a single area.

It should be understood that IC chips with different designs can be formed on the same semiconductor wafer using the disclosed photolithography method. Thus, when the various different patterns (i.e., the first pattern 201, the second pattern 202, etc.) in the framed pattern regions on the reticle 125 are designed to pattern feature layers at the same level for different IC chip designs, then the different sets of exposure processes can be performed one after the other without additional processing of the semiconductor wafer. That is, if the first pattern 201 is for patterning a layer at a specific level (e.g., at the active device level or some other specific level) of an IC chip being formed in a first target region of the semiconductor wafer 155 according to a first IC chip design and if the second pattern 202 is for patterning a layer at the same specific level of another IC chip being formed in a second target region of the semiconductor wafer 155 according to a second IC chip design, then the first set of exposure processes can be followed by the second exposure processes to transfer images into different portions of the same photosensitive layer in different target regions, respectively. Any adjustments to the exposure parameters (e.g., dose, etc.) can be made, as necessary, between the sets of exposure processes. In this case, after both sets of exposure processes are performed, the images of the patterns in the different portions of the photosensitive layer can simultaneously be transferred into corresponding portions of a feature layer (e.g., an active device layer, a gate polysilicon layer, etc.) below the photosensitive layer and in the different target regions, respectively. This transfer can be achieved using, for example, conventional photosensitive layer development and feature layer etch processes.

However, when the first pattern and the second pattern are designed for patterning feature layers at different levels of either the same IC chip design or different IC chip designs, the semiconductor wafer must subjected to additional processing between the first set of exposure processes and the second set of exposure processes (see process 410). This additional processing can include, but is not limited to, the following: transferring the first image of the first pattern from a portion of the photosensitive layer into a corresponding portion of a feature layer (e.g., an active device layer) below the photosensitive layer and in the first target region (e.g., by conventional photosensitive layer development and feature layer etch processes); depositing at least one additional feature layer to be patterned (e.g., deposition of a gate polysilicon layer on the active device layer); and depositing an additional photosensitive layer on the additional feature layer to be patterned. The second set of exposure processes can then be performed, after which, the second image of the second pattern can be transferred from a portion of the additional photosensitive layer into a corresponding portion of the additional feature layer below the additional photosensitive layer (e.g., by conventional photosensitive layer development and feature layer etch processes).

It should be understood that the terminology used herein is for the purpose of describing the disclosed structures and methods and is not intended to be limiting. For example, as used herein, the singular forms “a”, “an” and “the” are intended to include the plural forms as well, unless the context clearly indicates otherwise. Additionally, as used herein, the terms “comprises” “comprising”, “includes” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right”, “left”, “vertical”, “horizontal”, “top”, “bottom”, “upper”, “lower”, “under”, “below”, “underlying”, “over”, “overlying”, “parallel”, “perpendicular”, etc., are intended to describe relative locations as they are oriented and illustrated in the drawings (unless otherwise indicated) and terms such as “touching”, “in direct contact”, “abutting”, “directly adjacent to”, “immediately adjacent to”, etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Therefore, disclosed above are embodiments of a reticle structure that incorporates multiple different sets of redundant mask patterns. Each set of redundant mask patterns allows for patterning of a layer at a specific level of an integrated circuit (IC) chip design on a target region of a wafer using a vote-taking technique to avoid defects. Furthermore, the different sets of redundant mask patterns allow the same reticle to be used to pattern layers at different levels in the same IC chip design or to pattern layers at the same level or at different levels in different IC chip designs. The different IC chip designs can be at the same technology node or at different technology nodes. In any case, each mask pattern can be individually framed with alignment marks to facilitate alignment minimize overlay errors. Optionally, redundant mask patterns in the same set can be distributed across the reticle (as opposed to being located within the same general area) in order to minimize reticle overheating during patterning using the vote-taking technique. Also disclosed above are embodiments of a photolithography system and a photolithography method that employ such a reticle.

What is claimed is:

1. A reticle comprising:
a substrate;
pattern regions on the substrate and comprising at least:
multiple instances of a first pattern; and
multiple instances of a second pattern that is different from the first pattern;
frame regions on the substrate bordering the pattern regions, respectively; and
separation regions on the substrate between adjacent frame regions.

2. The reticle of claim 1, further comprising:
a reflective multilayer stack in the substrate;
a protective layer on the reflective multilayer stack; and
a light absorber layer on the protective layer, wherein the first pattern and the second pattern comprise different patterned portions of the light absorber layer.

3. The reticle of claim 2, further comprising an additional light absorber layer on the light absorber layer,
wherein the frame regions comprise patterned portions of the additional light absorber layer, and
wherein the separation regions comprise non-patterned portions of the light absorber layer that extend laterally between the adjacent frame regions.

4. The reticle of claim 2,
wherein the frame regions comprise trenches that extend vertically through the light absorber layer adjacent to the patterned portions of the light absorber layer, through the protective layer and through the reflective multilayer stack to the substrate, and
wherein the separation regions comprise non-patterned portions of the light absorber layer that extend laterally between the adjacent frame regions.

5. The reticle of claim 2,
wherein the frame regions comprise:
additional patterned portions of the light absorber layer laterally surrounding the patterned portions of the light absorber layer; and
trenches that extend vertically through the light absorber layer adjacent to the additional patterned portions of the light absorber layer and that further extend vertically through the protective layer and through the reflective multilayer stack to the substrate, and
wherein the separation regions comprise non-patterned portions of the light absorber layer that extend laterally between the adjacent frame regions.

6. The reticle of claim 1, wherein the first pattern and the second pattern represent shapes in different levels of an integrated circuit chip design.

7. The reticle of claim 1, wherein the first pattern and the second pattern represent shapes in either a same level or different levels of different integrated circuit chip designs.

8. The reticle of claim 1, wherein the multiple instances of the first pattern are located above a first area of the substrate and the multiple instances of the second pattern are located above a second area of the substrate.

9. The reticle of claim 1, wherein the multiple instances of the first pattern and the multiple instances of the second pattern are distributed essentially uniformly across the substrate.

10. The reticle of claim 1, wherein the pattern regions are arranged in any of the following:
columns and rows;
a single column; and
a single row.

11. A photolithography system comprising:
a reticle stage supporting a reticle, the reticle comprising:
a substrate;
pattern regions on the substrate and comprising at least:
multiple instances of a first pattern; and
multiple instances of a second pattern that is different from the first pattern;
frame regions on the substrate bordering the pattern regions, respectively; and
separation regions on the substrate between adjacent frame regions;
a light source;
a wafer stage supporting a wafer such that a surface of the wafer is adjacent to the pattern regions of the reticle; and
a controller controlling the reticle stage, the light source and the wafer stage,
wherein, during the controlling, the controller causes a first set of exposure processes and a second set of exposure processes to be performed,
wherein, during the first set of exposure processes, radiation from the light source is reflected off of each of the multiple instances of the first pattern, in sequence, toward a first target region on the wafer in order to transfer a first image of the first pattern into the first target region, and
wherein, during the second set of exposure processes, radiation from the light source is reflected off of each of the multiple instances of the second pattern, in sequence, toward a second target region on the wafer in order to transfer a second image of the second pattern into the second target region.

12. The photolithography system of claim 11, wherein the first set of exposure processes is performed to pattern a first layer and the second set of exposure processes is performed to pattern a second layer and wherein the first layer and the second layer are at different levels of an integrated circuit chip design.

13. The photolithography system of claim 11, wherein the first set of exposure processes is performed to pattern a first layer and the second set of exposure processes is performed to pattern a second layer and wherein the first layer and the second layer are either at a same level or at different levels of different integrated circuit chip designs.

14. The photolithography system of claim 11, wherein the multiple instances of the first pattern are located above a first area of the substrate and the multiple instances of the second pattern are located above a second area of the substrate.

15. The photolithography system of claim 11, wherein the multiple instances of the first pattern and the multiple instances of the second pattern are distributed essentially uniformly across the substrate to avoid overheating of the reticle during performance of either the first set of exposure processes or the second set of exposure processes.

16. A photolithography method comprising:
providing a reticle comprising:
a substrate;
pattern regions on the substrate and comprising at least:
multiple instances of a first pattern; and
multiple instances of a second pattern that is different from the first pattern;
frame regions on the substrate bordering the pattern regions, respectively; and
separation regions on the substrate between adjacent frame regions; and
performing a first set of exposure processes and a second set of exposure processes,
wherein, during the first set of exposure processes, radiation from a light source is reflected off of each of the multiple instances of the first pattern, in sequence, toward a first target region on a wafer in order to transfer a first image of the first pattern into the first target region, and
wherein, during the second set of exposure processes, radiation from the light source is reflected off of each of the multiple instances of the second pattern, in sequence, toward a second target region on the wafer in order to transfer a second image of the second pattern into the second target region.

17. The photolithography method of claim 16, wherein the first set of exposure processes is performed to pattern a first layer and the second set of exposure processes is performed to pattern a second layer and wherein the first layer and the second layer are at different levels of an integrated circuit chip design.

18. The photolithography method of claim 16, wherein the first set of exposure processes is performed to pattern a first layer and the second set of exposure processes is performed to pattern a second layer and wherein the first layer and the second layer are either at a same level or at different levels of different integrated circuit chip designs.

19. The photolithography method of claim 16, wherein the multiple instances of the first pattern are located above a first area of the substrate and the multiple instances of the second pattern are located above a second area of the substrate.

20. The photolithography method of claim 16, wherein the multiple instances of the first pattern and the multiple instances of the second pattern are distributed essentially uniformly across the substrate to avoid overheating of the reticle during performance of either the first set of exposure processes or the second set of exposure processes.
